(19) United States
(12) Patent Application Publication
(10) Pub. No.: US 2026/0164879 A1
(43) Pub. Date: Jun. 11, 2026

(54) LIGHT-EMITTING DEVICE

(71) Applicant: NICHIA CORPORATION, Anan-shi (JP)

(72) Inventors: Akihiro OTA, Anan-shi (JP); Eiji TOKUNAGA, Tokushima-shi (JP); Masato OKAWA, Anan-shi (JP)

(73) Assignee: NICHIA CORPORATION, Anan-shi (JP)

(21) Appl. No.: 19/179,857

(22) Filed: Apr. 15, 2025

(30) Foreign Application Priority Data
Apr. 17, 2024 (JP) 2024-066953
May 20, 2024 (JP) 2024-082209
Nov. 20, 2024 (JP) 2024-202528

(51) Int. Cl. H10H 29/24; H10H 29/01; H10H 29/85; H10H 29/851; H10H 29/853

(52) U.S. Cl. CPC H10H 29/24; H10H 29/8514; H10H 29/853; H10H 29/857; H10H 29/0362; H10H 29/0364; H10H 29/8512

(57) ABSTRACT

A light-emitting device includes: a first substrate having a first upper surface; light-emitting elements; a second substrate; a wire; a first dam structure surrounding the light-emitting elements; and an insulating member disposed outward of the first dam structure in a top view and having an inner end portion. In a cross section, when a distance between a straight line passing through the inner end portion and perpendicular to the first upper surface and a straight line passing through an outer end portion of an outermost light-emitting element and perpendicular to the first upper surface is defined as a first distance A, and a distance, in a height direction, between a top portion of the insulating member and a plane of the first upper surface is defined as a second distance B, the first distance A and the second distance B satisfy 0.1×B≤A≤B.

### CROSS-REFERENCE TO RELATED APPLICATIONS

This application is based on and claims priority to Japanese Patent Application No. 2024-066953, filed on Apr. 17, 2024, Japanese Patent Application No. 2024-082209, filed on May 20, 2024, and Japanese Patent Application No. 2024-202528, file on Nov. 20, 2024. The entire contents of these applications are incorporated herein by reference.

### BACKGROUND

### 1. Technical Field

The present disclosure relates to a light-emitting device.

### 2. Description of Related Art

Japanese Patent Publication No. 2017-212301 describes a light-emitting device including a submount substrate, one or more light-emitting elements mounted on the submount substrate, bonding wires connecting a circuit pattern and electrodes of the one of the light-emitting elements, and a protective resin disposed around the bonding wires so as to cover the bonding wires. In the above light-emitting device, when a light-shielding insulating member serving as the protective resin is disposed, light from the light-emitting elements is reflected by the insulating member, and stray light accompanying the reflection may be emitted.

### SUMMARY

An object of one embodiment of the present disclosure is to provide a light-emitting device that reduces stray light.

A light-emitting device according to one embodiment of the present disclosure includes a first substrate having a first upper surface; a plurality of light-emitting elements disposed on the first upper surface of the first substrate; a second substrate having a second upper surface on which the first substrate is disposed; a wire configured to electrically connect a first wiring part disposed on the first upper surface of the first substrate and outward of the plurality of light-emitting elements to a second wiring part disposed on the second upper surface of the second substrate; a first dam structure disposed on the first upper surface of the first substrate so as to surround the plurality of light-emitting elements; and a light-shielding insulating member disposed outward of the first dam structure in a top view, configured to cover the wire, the first wiring part, and the second wiring part, and having an inner end portion reaching the first dam structure. In a cross section passing through at least the first substrate, an outermost light-emitting element of the plurality of light-emitting elements, the first dam structure, and the insulating member, when a distance between a straight line passing through the inner end portion and perpendicular to the first upper surface and a straight line passing through an outer end portion of the outermost light-emitting element and perpendicular to the first upper surface is defined as a first distance A, and a distance, in a height direction of the light-emitting device, between a top portion of the insulating member and the first upper surface of the first substrate is defined as a second distance B, the first distance A and the second distance B satisfy a formula (1) below,

$$0.1 \times B \leq A \leq B . \qquad ( 1 )$$

### BRIEF DESCRIPTION OF THE DRAWINGS

FIG. 1 is a top view schematically illustrating the upper surface of a light-emitting device according to an embodiment;

FIG. 2 is a partial cross-sectional view schematically illustrating a cross section of a portion of the light-emitting device according to the embodiment, taken along line II-II of FIG. 1;

FIG. 3 is a graph illustrating an emission intensity distribution measured at positions located outward of the outer end portion of an outermost light-emitting element in each of Examples 4 to 8 and Comparative Example 1;

FIG. 4 is a graph illustrating a relationship between a first distance and the relative emission intensity of light in each of increase regions;

FIG. 5 is a graph illustrating a relationship between a third distance and the relative emission intensity of light in each of the increase regions;

FIG. 6 is a partial cross-sectional view schematically illustrating a cross section taken along the YZ plane, which illustrates a method of manufacturing the light-emitting device according to the embodiment;

FIG. 7 is a partial cross-sectional view schematically illustrating a cross section taken along the YZ plane, which illustrates the method of manufacturing the light-emitting device according to the embodiment;

FIG. 8 is a partial cross-sectional view schematically illustrating a cross section taken along the YZ plane, which illustrates the method of manufacturing the light-emitting device according to the embodiment;

FIG. 9 is a partial cross-sectional view schematically illustrating a cross section taken along the YZ plane, which illustrates the method of manufacturing the light-emitting device according to the embodiment;

FIG. 10 is a partial cross-sectional view schematically illustrating a cross section taken along the YZ plane, which illustrates the method of manufacturing the light-emitting device according to the embodiment;

FIG. 11 is a top view schematically illustrating the upper surface of a light-emitting device according to a first modification of the embodiment;

FIG. 12 is a partial cross-sectional view schematically illustrating a cross section of a part of the light-emitting device according to the first modification of the embodiment, taken along line XII-XII of FIG. 11;

FIG. 13 is a top view schematically illustrating the upper surface of a light-emitting device according to a second modification of the embodiment; and

FIG. 14 is a partial cross-sectional view schematically illustrating a cross section of a part of the light-emitting device according to the second modification of the embodiment, taken along line XIV-XIV of FIG. 13.

### DETAILED DESCRIPTION

Light-emitting devices according to embodiments of the present disclosure will be described in detail with reference to the accompanying drawings. The embodiments described below illustrate light-emitting devices that embody technical ideas underlying the present invention, but the present invention is not limited to the described embodiments. In addition, unless otherwise specified, the dimensions, materials, shapes, relative arrangements, and the like, of components described in the embodiments are not intended to limit the scope of the present invention thereto, but are described as examples. The sizes, positional relationships, and the like, of members illustrated in the drawings may be exaggerated for a better understanding of the structures. Further, in the following description, the same names and reference numerals refer to the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. A direction indicated by an arrow in the X-axis direction is referred to as a +X direction or a +X side, and a direction opposite to the +X direction is referred to as a −X direction or a −X side. A direction indicated by an arrow in the Y-axis direction is referred to as a +Y direction or a +Y side, and a direction opposite to the +Y direction is referred to as a −Y direction or a −Y side. A direction indicated by an arrow in the Z-axis direction is referred to as a +Z direction or a +Z side, and a direction opposite to the +Z direction is referred to as a −Z direction or a +Z side. The Z-axis direction corresponds to a “height direction” of each of the light-emitting devices. Further, the term “top view” as used in the embodiments refers to viewing an object in the +Z direction or from the +Z side. In the present specification, the phrase “in a top view” may be used to describe, in addition to a portion that can be directly seen from above, a portion that cannot be directly seen from above as if it can be seen from above. However, these directions do not limit the orientations of the light-emitting devices during use, and the orientations of the light-emitting devices are not particularly limited. In addition, in the embodiments, a surface of an object when viewed in the +Z direction or from the +Z side is referred to as an “upper surface,” and a surface of the object when viewed in the −Z direction or from the −Z side is referred to as a “lower surface.” In the embodiments described below, each of the phrases “along the X-axis,” “along the Y-axis,” and “along the Z-axis” includes a case where the object is at an inclination within a range of ±10° with respect to the corresponding one of the axes. Further, in the embodiments, the term “orthogonal” may include an error within ±10° of 90°.

Further, in the present disclosure, unless otherwise specified, polygonal shapes such as rectangular shapes, including polygonal shapes with rounded corners, beveled corners, angled corners, reverse-rounded corners, may be referred to as polygonal shapes. Further, not only shapes with such modification at corners (ends of sides) but also shapes with modifications at intermediate portions of sides of the shapes may also be referred to as polygonal shapes. That is, shapes that are based on polygonal shapes and partially modified are also interpreted as “polygonal shapes” in the present disclosure.

The same applies not only to polygonal shapes but also to terms representing specific shapes such as trapezoidal shapes, circular shapes, projections, and recesses. The same also applies when referring to sides forming such a shape. That is, even when a corner or an intermediate portion of a certain side is modified, the “side” is construed as including the modified portion.

Further, the term “cover” or “covering” is not limited to a case of direct contact, but also includes a case of indirectly covering a member via another member, for example. The term “disposing” is not limited to a case of direct contact, but also includes a case of indirectly disposing a member via another member, for example.

### Embodiments

### <Overall Configuration of Light-Emitting Device 1>

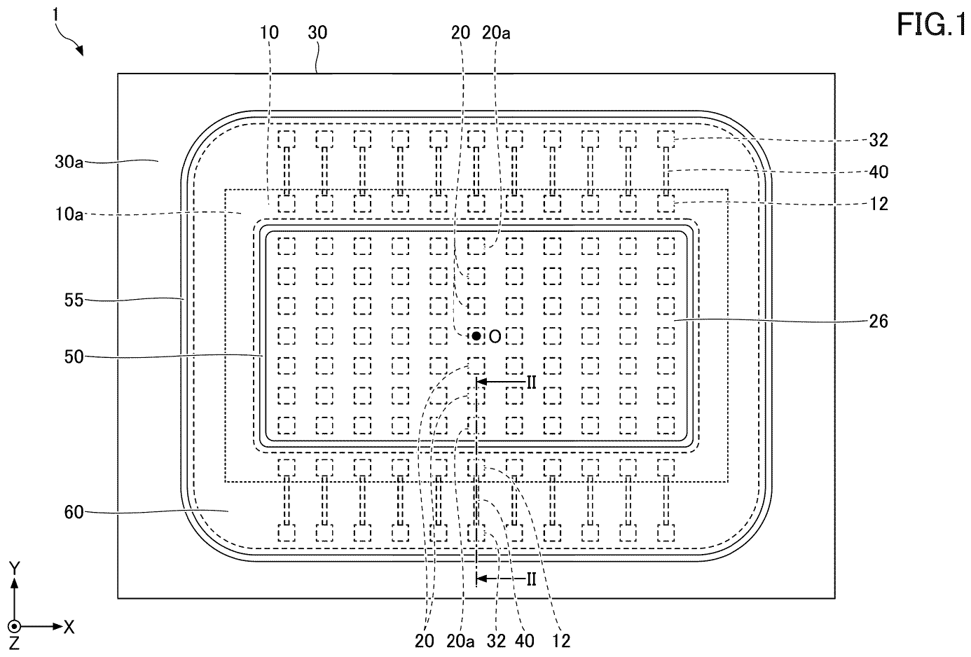

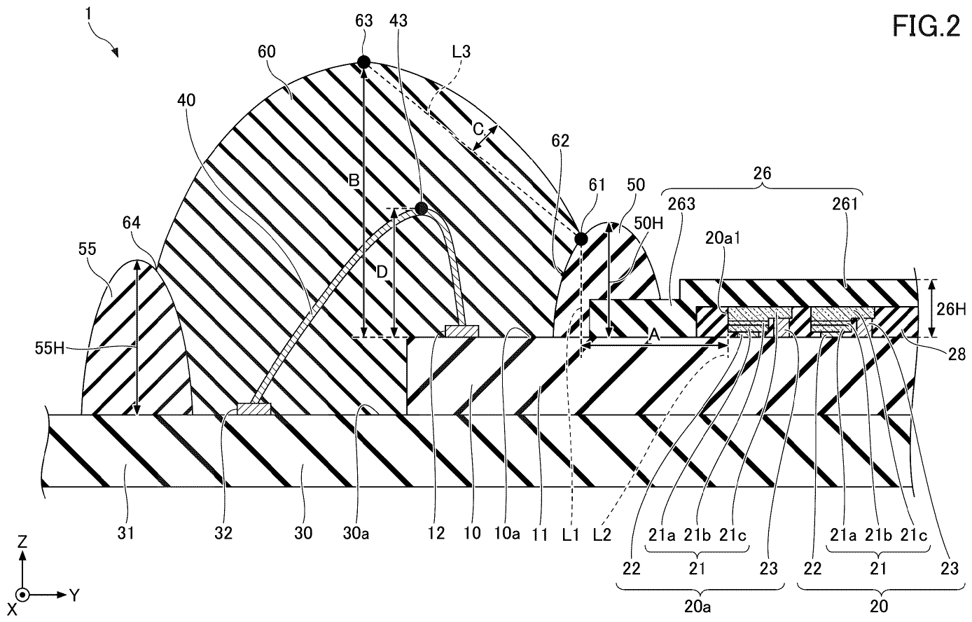

An example of a configuration of a light-emitting device 1 according to an embodiment will be described with reference to FIG. 1 and FIG. 2. FIG. 1 is a top view schematically illustrating the upper surface of the light-emitting device 1 according to the embodiment. FIG. 2 is a partial cross-sectional view schematically illustrating a cross section of a portion of the light-emitting device 1 according to the embodiment, taken along line II-II of FIG. 1. The cross section of the light-emitting device 1 illustrated in FIG. 2 is an example of a cross section passing through a first substrate, an outermost light-emitting element of a plurality of light-emitting elements, a first dam structure, and an insulating member (hereinafter may be simply referred to as “a cross section”). That is, in the description with reference to FIG. 2, “in a cross-sectional view” can be rephrased as “in a cross section.” The first substrate, the outermost light-emitting element of the plurality of light-emitting elements, the first dam structure, and the insulating member of the light-emitting device 1 will be described below.

As illustrated in FIG. 1 and FIG. 2, the light-emitting device 1 includes a first substrate 10, a plurality of light-emitting elements 20, a second substrate 30, a wire 40, a first dam structure 50, and a light-shielding insulating member 60. The light-shielding insulating member 60 is hereinafter simply referred to as the “insulating member 60.” The light-emitting device 1 may further include other components such as a phosphor layer 26, a light-shielding member 28, and a second dam structure 55. In FIG. 1, the first substrate 10, the plurality of light-emitting elements 20, the wire 40, a portion of the first dam structure 50, and a portion of the second dam structure 55 are illustrated in a perspective manner.

### <First Substrate 10>

The first substrate 10 has a first upper surface 10a, a lower surface, and lateral surfaces connecting the first upper surface 10a and the lower surface. As illustrated in FIG. 1, the first substrate 10 has a substantially rectangular outer shape in a top view. However, the first substrate 10 may have any other outer shape such as a substantially circular shape, a substantially elliptical shape, or a substantially polygonal shape in a top view. The first substrate 10 may include an integrated circuit for controlling the light emitting operation of each of the plurality of light-emitting elements 20. Examples of the integrated circuit include an electronic circuit such as an application specific integrated circuit (ASIC).

The first substrate 10 includes a first base 11 and a first wiring part 12. The first wiring part 12 is located outward of the plurality of light-emitting elements 20 in a top view. The first substrate 10 may further include other wirings such as inner layer wiring disposed inside the first base 11 and upper wiring disposed on the first upper surface 10a in a region overlapping a corresponding light-emitting element 20 in a top view. The first wiring part 12 and the corresponding light-emitting element 20 may be electrically connected to each other via the inner layer wiring and the upper wiring.

The first base 11 is a base member of the first substrate 10. In the example illustrated in FIG. 1 and FIG. 2, the first upper surface 10a of the first substrate 10 is defined by the upper surface of the first base 11. The lower surface of the first substrate 10 is defined by the lower surface of the first base 11. Further, the lateral surfaces of the first substrate 10 are defined by the lateral surfaces of the first base 11. The first base 11 is mainly composed of an insulator having an insulating property or composed of a semiconductor material. Examples of the material constituting the first base 11 include a semiconductor substrate such as silicon, a ceramic substrate such as aluminum nitride, and a resin substrate such as glass epoxy. However, the material constituting the first base 11 is not limited thereto.

The first wiring part 12 is disposed on the first upper surface 10a. The first substrate 10 preferably includes a plurality of first wiring parts 12. As illustrated in FIG. 1, in a top view, the plurality of first wiring parts 12 are disposed outward of the first dam structure 50 and along outer edges of the first dam structure 50. As used herein, “outward” refers to a side farther away from an object with respect to the geometric centroid O of the light-emitting device 1 in a top view. In contrast, “inward” refers to a side closer to the object with respect to the geometric centroid O of the light-emitting device 1 in a top view. The center of a light-emitting surface of the light-emitting device 1 may be used as a reference instead of the geometric centroid O of the light-emitting device 1 in a top view.

In the example illustrated in FIG. 1, some first wiring parts 12 of the plurality of first wiring parts 12 are disposed outward of the outer edge on the +Y side of the first dam structure 50 and arranged in a row along the X-axis direction. Some other first wiring parts 12 of the plurality of first wiring parts 12 are disposed outward of the outer edge on the −Y side of the first dam structure 50 and arranged in a row along the X-axis direction. In the example illustrated in FIG. 1, no first wiring parts 12 are disposed outward of the outer edge on the +X side of the first dam structure 50 and outward of the outer edge on the −X side of the first dam structure 50. However, first wiring parts 12 may be disposed outward of the outer edge on the +X side of the first dam structure 50 and outward of the outer edge on the −X side of the first dam structure 50.

Examples of a material constituting a first wiring part 12 include metals such as gold, silver, copper, aluminum, nickel, rhodium, titanium, platinum, palladium, molybdenum, chromium, and tungsten, and alloys of these metals. The first wiring part 12 may have a single-layer structure composed of one of these metals or alloys, or may have a layered structure in which a plurality of layers composed of any of these metals or alloys are layered.

### <Light-Emitting Elements 20>

Each of the plurality of light-emitting elements 20 is a semiconductor light-emitting element such as a light-emitting diode (LED) or a laser diode (LD). The plurality of light-emitting elements 20 are disposed on the first upper surface 10a of the first substrate 10. In the example illustrated in FIG. 1, the plurality of light-emitting elements 20 are arranged in a matrix on the first upper surface 10a in the X-axis direction and the Y-axis direction, for example. However, the plurality of light-emitting elements 20 may be arranged in a direction different from the X-axis direction and the Y-axis direction. For convenience of description, a light-emitting element 20 located on the outermost side among the plurality of light-emitting elements 20 may be hereinafter referred to as a “light-emitting element 20a.” For example, in FIG. 1, among the plurality of light-emitting elements 20, each of a light-emitting element 20 included in a column on the most +X side, a light-emitting element 20 included in a column on the most −X side, a light-emitting element 20 included in a row on the most +Y side, and a light-emitting element 20 included in a row on the most −Y side corresponds to the “light-emitting element 20a.” However, when the light-emitting elements 20 including the light-emitting element 20a are not distinguished, they are collectively referred to as “light-emitting elements 20.”

As illustrated in FIG. 2, each of the plurality of light-emitting elements 20 includes a semiconductor structure 21, a first electrode 22, and a second electrode 23. The semiconductor structure 21 emits, for example, blue light. The semiconductor structure 21 includes a first semiconductor layer 21a of a first conductivity type, an active layer 21b, and a second semiconductor layer 21c of a second conductivity type different from the first conductivity type. The first semiconductor layer 21a, the active layer 21b, and the second semiconductor layer 21c are stacked in this order along the Z-axis direction. One of the first semiconductor layer 21a and the second semiconductor layer 21c is an n-type semiconductor layer. The other of the first semiconductor layer 21a and the second semiconductor layer 21c is a p-type semiconductor layer. The active layer 21b may have a single quantum well (SQW) structure or a multiple quantum well (MQW) structure including a plurality of well layers.

Each of the first semiconductor layer 21a, the active layer 21b, and the second semiconductor layer 21c is formed of, for example, a nitride semiconductor. The nitride semiconductor includes a semiconductor of all compositions obtained by varying the composition ratio x and y within their ranges in the chemical formula InₓAl_{y}Ga_{1-x-y}N (0≤x, 0≤y, x+y≤1). The peak emission wavelength of light emitted from the active layer 21b is preferably 400 nm or more and 530 nm or less, more preferably 420 nm or more and 490 nm or less, and even more preferably 440 nm or more and 460 nm or less. The active layer 21b emits, for example, blue light. However, the peak emission wavelength of the light emitted from the active layer 21b is not limited thereto. Further, the semiconductor forming each of the first semiconductor layer 21a, the active layer 21b, and the second semiconductor layer 21c is not limited to the nitride semiconductor. The light emitted from the active layer 21b may be hereinafter referred to as “light emitted from the semiconductor structure 21” or “light emitted from a light-emitting element 20.”

The first electrode 22 and the second electrode 23 constitute a pair of positive and negative electrodes. That is, one of the first electrode 22 and the second electrode 23 is an anode electrode. The other of the first electrode 22 and the second electrode 23 is a cathode electrode. The first electrode 22 and the second electrode 23 are disposed on the lower surface of the semiconductor structure 21 at positions spaced apart from each other. Each of the first electrode 22 and the second electrode 23 may be composed of, for example, a metal or an alloy that is the same as or similar to that of the first wiring part 12.

The upper surface of the first electrode 22 is bonded to the first semiconductor layer 21a. Further, the lower surface of the first electrode 22 is bonded to upper wiring disposed on the first upper surface 10a of the first substrate 10. With this configuration, the first electrode 22 is electrically connected to the first wiring part 12. Further, the upper surface of the second electrode 23 is bonded to the second semiconductor layer 21c. The lower surface of the second electrode 23 is bonded to upper wiring that is disposed on the first upper surface 10a of the first substrate 10 and that is different from the upper wiring bonded to the lower surface of the first electrode 22. With this configuration, the second electrode 23 is electrically connected to the first wiring part 12.

### <Phosphor Layer 26>

As illustrated in FIG. 2, the phosphor layer 26 is disposed on the plurality of light-emitting elements 20. That is, the phosphor layer 26 surrounds the plurality of light-emitting elements 20 in a top view. The phosphor layer 26 converts the wavelength of at least a portion of light emitted from the light-emitting elements 20. Accordingly, light whose wavelength is converted by the phosphor layer 26, of the light emitted from the light-emitting elements 20, and light transmitted through the inside of the phosphor layer 26 without having its wavelength converted by the phosphor layer 26 are emitted from the upper surface of the phosphor layer 26. Mixed-color light of the lights is extracted from the light-emitting device 1.

The phosphor layer 26 includes a base material containing a light-transmissive material, and a phosphor contained inside the base or disposed at another position of the base. Examples of the light-transmissive material include resin materials, ceramics, and glass. In the present embodiment, the light-transmissive material constituting the base material of the phosphor layer 26 includes a resin material. Examples of the resin material include a silicone resin, a silicone-modified resin, an epoxy resin, an epoxy-modified resin, and a phenol resin. In particular, a silicone resin or a modified resin thereof with good light resistance and heat resistance is preferable. However, the light-transmissive material is not limited thereto.

Examples of the phosphor include yttrium aluminum garnet based phosphors (hereinafter referred to as “YAG phosphors,” for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, CasMgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAION based phosphors (for example, Ca(Si,Al)₁₂(O,N)₁₆:Eu), nitride based phosphors such as LSN based phosphors (for example, (La, Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca) AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂). The phosphor layer 26 according to the present embodiment contains an yttrium aluminum garnet (YAG) based phosphor having good heat resistance. For example, a portion of blue light emitted from a light-emitting element 20 is converted into yellow light by the YAG based phosphor. Accordingly, a portion of blue light emitted from the light-emitting element 20 and yellow light emitted from the YAG based phosphor are mixed, and as a result, white light is emitted from the upper surface of the phosphor layer 26.

The length of the phosphor layer 26 along the Z-axis direction, that is, a thickness 26H of the phosphor layer 26, is preferably 28 μm or less. The thickness 26H of the phosphor layer 26 is more preferably 27 μm or less. By setting the thickness 26H of the phosphor layer 26 to be as thin as 28 μm or less, the distance by which light incident on the lower surface of the phosphor layer 26 travels within the phosphor layer 26 before exiting from the upper surface of the phosphor layer 26 can be reduced. By reducing the distance by which light travels within the phosphor layer 26, the amount of light scattering within the phosphor layer 26 is reduced. This can reduce the possibility that light emitted from the phosphor layer 26 spreads in a wide range equal to a desired angle or more. As a result, light from a light-emitting element 20 that performs a light emitting operation is less likely to pass above a light-emitting element 20 that does not perform a light emitting operation. That is, the contrast ratio between the luminance of a light-emitting region overlapping the light-emitting element 20 that emitted light and the luminance of a non-light-emitting region overlapping the light-emitting element 20 that does not emit light can be improved in a top view.

In a case where the thickness 26H of the phosphor layer 26 is 28 μm or less, the phosphor layer 26 preferably contains a phosphor having an average particle diameter of 1 μm or more and 5 μm or less. By using a phosphor having an average particle diameter of 1 μm or more and 5 μm or less, the concentration of the phosphor that can be contained in the phosphor layer 26 can be adjusted in a wider range, and the chromaticity of light emitted from the light-emitting device 1 can be easily adjusted to a desired chromaticity. Further, in a case where a phosphor having an average particle diameter of 1 μm or more and 5 μm or less is used, the phosphor layer 26 preferably contains a rare earth aluminate phosphor having a composition represented by the following formula (I). As an example, an average particle diameter can be measured by a Fisher Sub-Sieve Sizer method (hereinafter referred to as an “FSSS method”). The rare earth aluminate phosphor is a phosphor containing a rare earth metal element such as Y, La, Lu, Gd, or Tb and having a garnet crystal structure. Examples of the rare earth aluminate phosphor include YAG phosphors, lutetium aluminum garnet based phosphors, and terbium aluminum garnet based phosphors.

$${Y}_{( 3 - y )} {Al}_{( 5 - x )} {Ga}_{x} {O}_{12} : {Ce}_{y} \qquad ( I )$$

In the formula (I), x and y are numbers satisfying 0.00<x≤3.00 and 0.015≤y≤0.20, respectively.

In the case of the rare earth aluminate phosphor having the composition represented by the formula (I), the wavelength of light emitted from the phosphor can be adjusted by adjusting a Ga composition ratio x and a Ce composition ratio y. For example, the peak emission wavelength of light emitted from the phosphor tends to be shifted to the short wavelength side by increasing the Ga composition ratio x, and the emission peak wavelength of light emitted from the phosphor tends to be shifted to the long wavelength side by increasing the Ce composition ratio y. Further, by increasing the Ce composition ratio y, the absorptance of the phosphor tends to be improved, and the luminance of light emitted from the phosphor tends to be improved. Therefore, in the formula (I), by setting the Ce composition ratio y within the above range and making the Ce composition ratio relatively large, the luminance of light emitted from the phosphor can be increased, and by setting the Ga composition ratio x within the above range and making the Ga composition ratio relatively large, light is less likely to be shifted to a longer wavelength due to an increase in the Ce composition ratio y. In the above formula (I), the numerical range of x is 0.00<x≤3.00, preferably 0.10≤x≤1.00, and more preferably 0.25≤x≤0.60. Further, in the above formula (I), the numerical range of y is 0.015≤y≤0.20, preferably 0.03≤y≤0.15, and more preferably 0.07≤y≤0.10.

Examples of preferred configurations of the phosphor layer 26 include a configuration (1) in which the thickness 26H of the phosphor layer 26 is 28 μm or less, a configuration (2) in which a phosphor having an average particle diameter of 1 μm or more and 5 μm or less is used, and a configuration (3) in which, as the phosphor, a phosphor including a rare earth aluminate phosphor having a composition represented by the formula (I) is used. Accordingly, the contrast ratio of the light-emitting device 1 can be improved by using the phosphor layer 26 having the thickness 26H of 28 μm or less, which is relatively small, and also a desired chromaticity can be obtained by using a phosphor having a small average particle diameter. Furthermore, by using a phosphor represented by the above formula (I), which has a small particle diameter and a high luminance, the luminance of the light-emitting device 1 can be improved.

The phosphor layer 26 contains, for example, a resin portion as a base material and a phosphor including a rare earth aluminate phosphor represented by the formula (I). As described above, the material constituting the resin portion may be a light-transmissive resin material such as a silicone resin, a silicone-modified resin, an epoxy resin, an epoxy-modified resin, or a phenol resin. For example, the content of the phosphor including the rare earth aluminate phosphor in the phosphor layer 26 is 100 parts by mass or more and 150 parts by mass or less, preferably 100 parts by mass or more and 140 parts by mass or less, and more preferably 110 parts by mass or more and 130 parts by mass or less with respect to 100 parts by mass of the resin portion. By setting the content of the phosphor including the rare earth aluminate phosphor to be within the above range, the amount of light emitted from a light-emitting element 20 and scattered by the phosphor can be reduced, and the light extraction efficiency of the light-emitting device 1 can be improved. The content (parts by mass) of the phosphor with respect to 100 parts by mass of the resin portion may be hereinafter referred to as the “concentration of the phosphor.” The concentration of the phosphor may be expressed in terms of “per hundred resin (phr).”

The phosphor layer 26 may contain another rare earth aluminate phosphor having a composition represented by the following formula (II) in addition to the rare earth aluminate phosphor represented by the above formula (I).

$${Y}_{( 3 - x - z )} {Gd}_{z} {Al}_{( 5 - y )} {Ga}_{y} {O}_{12} : {Ce}_{x} \qquad ( II )$$

In the formula (II), x, y, and z are numbers satisfying 0.015≤x≤0.15, 0.01≤y≤0.10, and 0.00≤z≤0.13, respectively.

Experimental Examples 1 to 3 will be described with reference to Tables 1 to 3.

TABLE 1

| | CONCENTRATION | HEIGHT OF | | |
|---|---|---|---|---|
| | OF | PHOSPHOR | | CONTRAST |
| | PHOSPHOR | LAYER | LUMINANCE | RATIO |
| | (phr) | (μm) | (%) | (%) |
| EXPERIMENTAL | 160 | 30 | 100.0 | 12.1 |
| EXAMPLE 1 | | | | |
| EXPERIMENTAL | 160 | 25 | 94.0 | 7.7 |
| EXAMPLE 2 | | | | |
| EXPERIMENTAL | 120 | 25 | 98.9 | 7.9 |
| EXAMPLE 3 | | | | |

TABLE 2

| | | | | | AVERAGE | CHROMATICITY | | |
|---|---|---|---|---|---|---|---|---|
| | COMPOSITION RATIO | | | | PARTICLE | x | y | ABSORPTANCE |
| | (MOLAR RATIO) | | | | DIAMETER | COOR- | COOR- | (%) |
| | Y | Ce | Al | Ga | (μm) | DINATE | DINATE | AT 450 nm |
| EXAMPLE 1 | 2.915 | 0.085 | 4.72 | 0.28 | 3.3 | 0.442 | 0.536 | 84.5 |
| REFERENCE | 2.936 | 0.064 | 5.12 | 0 | 3.2 | 0.441 | 0.537 | 81.1 |
| EXAMPLE 1 | | | | | | | | |

TABLE 3

| | | | | | | AVERAGE | CHROMATICITY | | |
|---|---|---|---|---|---|---|---|---|---|
| | COMPOSITION RATIO | | | | | PARTICLE | x | y | ABSORPTANCE |
| | (MOLAR RATIO) | | | | | DIAMETER | COOR- | COOR- | (%) |
| | Y | Gd | Ce | Al | Ga | (μm) | DINATE | DINATE | AT 450 nm |
| EXAMPLE 2 | 2.895 | 0 | 0.105 | 4.96 | 0.04 | 4.3 | 0.464 | 0.521 | 11.8 |
| REFERENCE | 2.691 | 0.142 | 0.167 | 5.06 | 0 | 3.9 | 0.465 | 0.521 | 14.3 |
| EXAMPLE 2 | | | | | | | | | |

Table 1 indicates characteristic evaluation results in Experimental Examples 1 to 3. In Table 1 “luminance (%)” corresponds to a percentage of luminance when the luminance in Experimental Example 1 is set to 100%. Further, in Table 1, a “contrast ratio (%)” corresponds to, for example, a percentage of the luminance of a non-light-emitting region overlapping, in a top view, a light-emitting element 20 that does not emit light and that is separated by a predetermined number of light-emitting elements (for example, two light-emitting elements) from a light-emitting element 20 that emits light, with respect to the luminance of a light-emitting region overlapping, in a top view, the light-emitting element 20 that emits light. The lower the numerical value of the “contrast ratio (%),” the lower the luminance of the non-light-emitting region, that is, the higher the contrast between the luminance of the light-emitting region and the luminance of the non-light-emitting region.

First, in Experimental Example 1, the thickness 26H of a phosphor layer 26 was 30 μm, and a rare earth aluminate phosphor having an average particle diameter of 8 μm was used. The phosphor in Experimental Example 1 is a YAG phosphor containing neither Ga nor Gd. In Experimental Example 2, the thickness 26H of a phosphor layer 26 was 25 μm, and a rare earth aluminate phosphor of Reference Example 1 in Table 2 and a rare earth aluminate phosphor of Reference Example 2 in Table 3, which serves as a phosphor for chromaticity adjustment, were used in combination. The rare earth aluminate phosphor of Reference Example 1 is a phosphor having an average particle diameter of 1 μm or more and 5 μm or less, but does not contain Ga and thus does not satisfy the above formula (I). In the Experimental Example 3, the thickness 26H of a phosphor layer 26 was 25 μm, and a rare earth aluminate phosphor of Example 1 in Table 2 and a rare earth aluminate phosphor of Example 2 in Table 3, which serves as a phosphor for chromaticity adjustment, were used in combination. The rare earth aluminate phosphor of Example 1 is a phosphor having an average particle diameter of 1 μm or more and 5 μm or less and satisfying the above formula (I). An “average particle diameter” in Table 2 and Table 3 is an average particle diameter measured by the FSSS method. An “x coordinate” and a “y coordinate” of “chromaticity” in Table 2 and Table 3 correspond to an x coordinate and a y coordinate of the chromaticity diagram of JIS Z8110, for example. An “absorptance (%) at 450 nm” in Table 2 and Table 3 corresponds to the absorptance of excitation light by a phosphor when the excitation light having a peak emission wavelength of 450 nm is emitted. When the intensity of the excitation light is defined as “α0” and the intensity of light transmitted through the phosphor without being absorbed by the phosphor is defined as “α,” the “absorptance (%) at 450 nm” is calculated by, for example, “{1−(α/α0)}×100.”

As indicated in Table 1, as compared to Experimental Example 1, the contrast ratio of a light-emitting device 1 of Experimental Example 2 was improved by setting the thickness 26H of the phosphor layer 26 to 28 μm or less. In addition, by using the phosphors each having an average particle diameter of 1 μm or more and 5 μm or less, the light-emitting device 1 having substantially the same chromaticity range as that of a light-emitting device 1 of Experimental Example 1 was obtained in Experimental Example 2 while maintaining the concentration of the phosphors. Further, as compared to Experimental Example 2, a light-emitting device 1 having a high luminance was obtained in Experimental Example 3 by using the rare earth aluminate phosphors each having a small particle diameter and represented by the formula (I). The chromaticity range of the light-emitting device 1 of Experimental Example 3 was substantially the same as those the light-emitting device 1 of Experimental Example 1 and the light-emitting device 1 of Experimental Example 2.

Next, an example configuration of a phosphor layer 26 will be described in more detail. As illustrated in FIG. 2, the phosphor layer 26 includes a body portion 261 and an extending portion 263. The body portion 261 is disposed at a position overlapping a plurality of light-emitting elements 20 in a top view. For example, the body portion 261 includes a flat plate-shaped region collectively covering the upper surfaces of the plurality of light-emitting elements 20. However, the configuration of the body portion 261 is not limited thereto.

The extending portion 263 is continuous with the body portion 261 and extends outward from the outer edges of the body portion 261 in a top view. In FIG. 2, only a region of the extending portion 263 continuous with the outer edge on the −Y side of the body portion 261 is illustrated; however, the extending portion 263 has regions continuous with the outer edge on the +Y side of the body portion 261, continuous with the outer edge on the +X side of the body portion 261, and continuous with the outer edge on the −X side of the body portion 261. In other words, the extending portion 263 is disposed so as to surround the body portion 261 in a top view.

### <Light-Shielding Member 28>

The light shielding member 28 covers the lateral surfaces of each of the plurality of light-emitting elements 20. The light shielding member 28 preferably has light reflectivity. By causing the light-shielding member 28 having light reflectivity to cover the lateral surfaces of the plurality of light-emitting elements 20, light emitted from the light-emitting elements 20 can be directed toward the body portion 261 of the phosphor layer 26, for example. Further, by disposing the light-shielding member 28 between adjacent ones of the plurality of light-emitting elements 20, light from a light-emitting element 20 that performed a light emitting operation is less likely to pass above a light-emitting element 20 that did not perform a light emitting operation can be reduced. Accordingly, the contrast ratio between the luminance of a light-emitting region overlapping the light-emitting element 20 that emitted light and the luminance of a non-light-emitting region overlapping the light-emitting element 20 that did not emit light can be improved in a top view.

The light-shielding member 28 is composed of, for example, a resin material containing a light reflective substance. Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. It is preferable to use one of the above substances alone or a combination of two or more of the above substances. Examples of the resin material include a resin material whose main component is a thermosetting resin such as an epoxy resin, an epoxy-modified resin, a silicone resin, a silicone-modified resin, and a phenol resin.

### <Second Substrate 30>

The second substrate 30 has a second upper surface 30a, a lower surface, and lateral surfaces connecting the second upper surface 30a and the lower surface. As illustrated in FIG. 2, the first substrate 10 is disposed on the second upper surface 30a. The second upper surface 30a of the second substrate 30 and the lower surface of the first substrate 10 may be directly bonded to each other, or may be bonded to each other via, for example, a bonding member. As illustrated in FIG. 1, the second substrate 30 has a substantially rectangular outer shape in a top view. However, the second substrate 30 may have any other outer shape such as a substantially circular shape, a substantially elliptical shape, or a substantially polygonal shape in a top view.

A second base 31 is a base member of the second substrate 30. The second upper surface 30a of the second substrate 30 is defined by the upper surface of the second base 31. Further, the lower surface of the second substrate 30 is defined by the lower surface of the second base 31. Further, the lateral surfaces of the second substrate 30 are defined by the lateral surfaces of the second base 31. Similar to the first base 11 of the first substrate 10, the second base 31 is mainly composed of an insulator having an insulating property or composed of a semiconductor. However, the material constituting the second base 31 is not limited thereto.

A second wiring part 32 is disposed on the second upper surface 30a. The second substrate 30 preferably includes a plurality of second wiring parts 32. As illustrated in FIG. 1, the plurality of second wiring parts 32 are disposed outward of the first substrate 10 and along outer edges of the first substrate 10 in a top view.

In the example illustrated in FIG. 1, some second wiring parts 32 of the plurality of second wiring parts 32 are disposed outward of the outer edge on the +Y side of the first substrate 10 and arranged in a row along the X-axis direction. Some other second wiring parts 32 of the plurality of second wiring parts 32 are disposed outward of the outer edge on the −Y side of the first substrate 10 and arranged in a row along the X-axis direction. That is, the plurality of second wiring parts 32 face the plurality of first wiring parts 12 with the outer edges of the first substrate 10 interposed therebetween in a top view. In the example illustrated in FIG. 1, no second wiring parts 32 are disposed outward of the outer edge on the +X side of the first substrate 10 and outward of the outer edge on the −X side of the first substrate 10. However, second wiring parts 32 may be disposed outward of the outer edge on the +X side of the first substrate 10 and outward of the outer edge on the −X side of the first substrate 10.

Each of the plurality of second wiring parts 32 may be composed of a metal or an alloy the same as or similar to that of the first wiring parts 12. Further, similar to the first wiring parts 12, each of the second wiring parts 32 may have a single-layer structure composed of a metal or an alloy, or may have a layered structure in which a plurality of layers composed of a metal or an alloy are layered.

### <Wire 40>

The wire 40 electrically connects a first wiring part 12 disposed on the first upper surface 10a of the first substrate 10 and a second wiring part 32 disposed on the second upper surface 30a of the second substrate 30. The wire 40 is, for example, a conductive wire, a ribbon wire, or the like. In the example illustrated in FIG. 1, a plurality of wires 40 are provided so as to connect the plurality of first wiring parts 12 and the plurality of second wiring parts 32, which face each other with the outer edges of the first substrate 10 interposed therebetween in a top view. The first wiring parts 12 and the second wiring parts 32 are electrically connected to each other via the wires 40, and thus the first wiring parts 12 are electrically connected to an external power source via the second wiring parts 32 and the wires 40. That is, power from the external power source is supplied to the light-emitting elements 20 via the second wiring parts 32, the wires 40, and the first wiring parts 12.

Examples of a material constituting each of the plurality of wires 40 include metals such as gold, copper, platinum, and aluminum, and alloys of these metals. However, the material constituting each of the wires 40 is not limited to these metals and alloys.

As illustrated in FIG. 2, a wire 40 has a curved shape including a top portion 43. That is, the top portion 43 of the wire 40 is located at a position higher than a bonding portion of the wire 40 bonded to a first wiring part 12 and a bonding portion of the wire 40 bonded to a second wiring part 32. The top portion 43 of the wire 40 may be located at a position higher than the upper surfaces of the light-emitting elements 20 and the upper surface of the body portion 261 of the phosphor layer 26.

### <First Dam Structure 50>

As illustrated in FIG. 1 and FIG. 2, the first dam structure 50 is disposed on the first upper surface 10a of the first substrate 10. The first dam structure 50 is disposed so as to surround the plurality of light-emitting elements 20. In the example illustrated in FIG. 1 and FIG. 2, the first dam structure 50 is a frame-shaped structure protruding upward from the first upper surface 10a. However, the first dam structure 50 is not limited to the frame-shaped structure protruding upward from the first upper surface 10a.

As illustrated in FIG. 2, the first dam structure 50 is preferably disposed so as to straddle the extending portion 263 of the phosphor layer 26 and the first upper surface 10a of the first substrate 10. That is, an inner region of the first dam structure 50 is disposed on the extending portion 263 of the phosphor layer 26. With this configuration, the extending portion 263 is engaged with the first upper surface 10a by the first dam structure 50. As a result, the possibility that the phosphor layer 26 is delaminated from the first upper surface 10a and the upper surfaces of the light-emitting elements 20 can be reduced. Further, the inner region of the first dam structure 50 overlaps the outer edges of the extending portion 263 in a top view. Therefore, even if the outer edges of the extending portion 263 have a geometrically asymmetric shape that meanders irregularly, the outer edges of the extending portion 263 are covered by the first dam structure 50, and thus the appearance of the light-emitting device 1 is less likely to deteriorate. However, the first dam structure 50 may be disposed so as to be separated from the phosphor layer 26.

As illustrated in FIG. 2, the first dam structure 50 has a substantially semi-elliptical shape protruding upward in a cross-sectional view. However, the shape of the first dam structure 50 in a cross-sectional view is not limited to the substantially semi-elliptical shape. The shape of the first dam structure 50 in a cross-sectional view may be any other shape such as a substantially semi-circular shape, a substantially triangular shape, a substantially rectangular shape, or a substantially polygonal shape protruding upward.

A top portion of the first dam structure 50 is preferably higher than the upper surface of the body portion 261 of the phosphor layer 26. That is, a height 50H of the first dam structure 50 from the first upper surface 10a is preferably higher than the height of the phosphor layer 26 from the first upper surface 10a. The height 50H of the first dam structure 50 from the first upper surface 10a means the height of the top portion of the first dam structure 50 from the first upper surface 10a. The height 50H of the first dam structure 50 from the first upper surface 10a is hereinafter referred to as the “height 50H of the first dam structure 50.” The first dam structure 50 functions to dam the insulating member 60. Because the top portion of the first dam structure 50 is higher than the upper surface of the body portion 261 of the phosphor layer 26, the insulating member 60 is easily dammed so as not to flow to the phosphor layer 26 side.

The first dam structure 50 is preferably a light-transmissive member. As used herein, “light transmissive” refers to having a light transmittance of at least 60% or more and preferably 80% more with respect to light emitted from the light-emitting elements 20 or the phosphor layer 26. When the first dam structure 50 is a light-transmissive member, the possibility that light emitted from the outermost light-emitting element 20a is reflected by the first dam structure 50 and becomes stray light as will be described later can be reduced as compared to when the first dam structure 50 is a light reflective member. Further, if the first dam structure 50 is a light reflective member, multiple reflections of light would occur between the first dam structure 50 and the body portion 261, and the boundary between the first dam structure 50 and the body portion 261 would appear bright (appear as a bright line) in a top view. Conversely, when the first dam structure 50 is the light-transmissive member, multiple reflections of light between the first dam structure 50 and the body portion 261 can be reduced, and light with less luminance unevenness can be emitted. Examples of a material constituting the first dam structure 50 include a resin material whose main component is a thermosetting resin such as an epoxy resin, an epoxy-modified resin, a silicone resin, a silicone-modified resin, and a phenol resin. However, the material constituting the first dam structure 50 is not limited thereto. The first dam structure 50 may be a member having light reflectivity or light absorbability.

It is preferable that the first dam structure 50 does not overlap the body portion 261 of the phosphor layer 26 in a top view. This can reduce the possibility of an excessively small distance between the insulating member 60 dammed by the first dam structure 50 and the outermost light-emitting element 20a. As a result, for example, the possibility that light emitted from the outermost light-emitting element 20a is transmitted through the phosphor layer 26 and the first dam structure 50 and reaches the insulating member 60 can be reduced. Light that has reached the insulating member 60 is likely to be reflected by the surface of the insulating member 60 and emitted to the outside of the light-emitting device 1. In such a case, the light reflected by the surface of the insulating member 60 would become stray light, which is emitted from, for example, a region that is different from the upper surface of the body portion 261 of the phosphor layer 26 to the outside of the light-emitting device 1. In the present embodiment, the possibility that stray light is emitted from the light-emitting device 1 can be reduced by relatively increasing the distance between the insulating member 60 and the outermost light-emitting element 20a, with the first dam structure 50 interposed therebetween.

### <Second Dam Structure 55>

The second dam structure 55 is disposed on the second upper surface 30a of the second substrate 30. As illustrated in FIG. 1, the second dam structure 55 is disposed in a frame shape so as to surround the first substrate 10 in a top view. As illustrated in FIG. 2, the second dam structure 55 protrudes upward from the second upper surface 30a in a cross-sectional view. In the example illustrated in FIG. 2, the shape of the second dam structure 55 in a cross-sectional view is a substantially semi-elliptical shape protruding upward. However, the shape of the second dam structure 55 in a cross-sectional view is not limited to the substantially semi-elliptical shape. The shape of the second dam structure 55 in a cross-sectional view may be any other shape such as a substantially semi-circular shape, a substantially triangular shape, a substantially rectangular shape, or a substantially polygonal shape protruding upward.

The second dam structure 55 functions to dam the insulating member 60.

That is, the inward movement and the outward movement of the insulating member 60 are dammed by the combination of the second dam structure 55 and the first dam structure 50 located inward of the second dam structure 55.

A height 55H of the second dam structure 55 from the second upper surface 30a (hereinafter, referred to as the “height 55H of the second dam structure 55”) is preferably higher than the height 50H of the first dam structure 50. The height 55H of the second dam structure 55 means the height of a top portion of the second dam structure 55 from the second upper surface 30a. As illustrated in FIG. 2, the volume of a region of the insulating member 60 located outward relative to a top portion 63 of the insulating member 60 is larger than the volume of a region of the insulating member 60 located inward relative to the top portion 63 of the insulating member 60. Therefore, by setting the height 55H of the second dam structure 55 to be greater than the height 50H of the first dam structure 50, the insulating member 60 can be dammed more reliably. In the example illustrated in FIG. 2, the second dam structure 55 is composed of a single protruding member. However, the second dam structure 55 may be composed of a plurality of protruding members that are connected to each other in the Z-axis direction. As an example of making the height 55H of the second dam structure 55 greater than the height 50H of the first dam structure 50, the first dam structure 50 may be composed of a single protruding member, and the second dam structure 55 may be composed of a layered structure in which two or more protruding members are connected to each other.

The second dam structure 55 is preferably a light-transmissive member. Examples of a material constituting the second dam structure 55 include a resin material whose main component is a thermosetting resin such as an epoxy resin, an epoxy-modified resin, a silicone resin, a silicone-modified resin, and a phenol resin. However, the material constituting the second dam structure 55 is not limited thereto. The second dam structure 55 may be a member having light reflectivity or light absorbability.

### <Insulating Member 60>

As illustrated in FIG. 1, the insulating member 60 is disposed outward of the first dam structure 50 in a top view. Further, the insulating member 60 is disposed inward of the second dam structure 55 in a top view. That is, the insulating member 60 is disposed in a frame shape in a region between the first dam structure 50 and the second dam structure 55 so as to surround the first dam structure 50 in a top view.

As illustrated in FIG. 2, the insulating member 60 protrudes upward from the first upper surface 10a of the first substrate 10 and the second upper surface 30a of the second substrate 30 in a cross-sectional view. The insulating member 60 is disposed so as to straddle the first upper surface 10a and the second upper surface 30a. Thus, the insulating member 60 covers a plurality of first wiring parts 12, a plurality of second wiring parts 32, and a plurality of wires 40. That is, the insulating member 60 protects the plurality of first wiring parts 12, the plurality of second wiring parts 32, and the plurality of wires 40, and prevents the plurality of wires 40 and the like from being exposed to the outside in a top view.

The insulating member 60 includes a resin containing a filler having a light shielding property. Examples of the resin include a silicone resin, a modified-silicone resin, an epoxy resin, a modified-epoxy resin, and an acrylic resin. Examples of the filler having a light shielding property include light absorbing substances such as pigments, carbon black, titanium black, and graphite; and light reflective substances such as titanium oxide, aluminum oxide, zinc oxide, barium carbonate, barium sulfate, boron nitride, aluminum nitride, and a glass filler. The external color of the insulating member 60 is, for example, white having good light reflectivity. However, the external color of the insulating member 60 may be any other color such as gray having light reflectivity and light absorbability.

As illustrated in FIG. 2, in a cross section, the insulating member 60 has an inner end portion 61, a recessed portion 62, the top portion 63, and an outer end portion 64. The insulating member 60 contacts the first dam structure 50 at the inner end portion 61 and the recessed portion 62. In addition, the insulating member 60 contacts the second dam structure 55 at the outer end portion 64. The top portion 63 of the insulating member 60 is located at a position higher than the top portion 43 of the wire 40. The inward movement of the insulating member 60 is dammed by the first dam structure 50. The outward movement of the insulating member 60 is dammed by the second dam structure 55.

The inner end portion 61 is the innermost portion of the insulating member 60. As illustrated in FIG. 2, the inner end portion 61 is located at a position higher than the upper surfaces of the light-emitting elements 20 in a cross-sectional view. For example, the inner end portion 61 is located at a position higher than the upper surface of the outermost light-emitting element 20a in a cross-sectional view. Further, the inner end portion 61 is located at a position higher than each of the upper surface of the body portion 261 and the upper surface of the extending portion 263 of the phosphor layer 26 in a cross-sectional view. Further, the inner end portion 61 is preferably located at approximately the same position as the top portion of the first dam structure 50 or located outward of the top portion of the first dam structure 50 in a cross-sectional view. With this configuration, the inward movement of the insulating member 60 can be reliably dammed, and also the possibility that the insulating member 60 extends beyond the top portion of the first dam structure 50, thereby decreasing the distance between the insulating member 60 and the outermost light-emitting element 20a can be reduced. That is, stray light is less likely to be emitted from the light-emitting device 1.

In a cross-sectional view illustrated in FIG. 2, a straight line L1 passes through the inner end portion 61 while being perpendicular to the first upper surface 10a, and a straight line L2 passes through an outer end portion 20a1 of the outermost light-emitting element 20a while being perpendicular to the first upper surface 10a. A distance between the straight line L1 and the second straight line L2 is defined as a first distance A. The first distance A is preferably 50 μm or more and 490 μm or less. The first distance A is more preferably 200 μm or more and 490 μm or less, and even more preferably 400 μm or more and 490 μm or less. By setting the first distance A to 50 μm or more, the possibility that the distance between the insulating member 60 and the outermost light-emitting element 20a is excessively small, and the amount of light emitted from the light-emitting element 20a and reaching the insulating member 60 can be reduced. That is, stray light is less likely to be emitted from the light-emitting device 1. In addition, by setting the first distance A to 490 μm or less, the size of the light-emitting device 1 can be reduced.

As illustrated in FIG. 2, the recessed portion 62 extends from the inner end portion 61 to the first upper surface 10a of the first substrate 10 in a cross-sectional view. Substantially the entire region of the recessed portion 62 contacts the surface of the first dam structure 50. The recessed portion 62 is recessed so as to correspond to the curvature of the surface of the first dam structure 50 in a cross-sectional view. That is, a line normal to the surface of the insulating member 60 defining the recessed portion 62 faces the first upper surface 10a. this configuration can reduce the possibility, for example, that light emitted from a lateral surface of the outermost light-emitting element 20a, transmitted through the phosphor layer 26 and the first dam structure 50, and reaching the recessed portion 62 is reflected upward. As a result, stray light is less likely to be emitted from the light-emitting device 1.

A region of the surface of the insulating member 60 located inward of the top portion 63 extends from the top portion 63 to the inner end portion 61. In a cross-sectional view illustrated in FIG. 2, a straight line L3 connects the inner end portion 61 to the top portion 63, and a region on the surface of the insulating member 60 is located between the inner end portion 61 and the top portion 63. A longest distance between the straight line L3 and the aforementioned region is defined as a third distance C. The third distance C is preferably 30 μm or more and 160 μm or less. The third distance C is more preferably 40 μm or more and 85 μm or less, and even more preferably 55 μm or more and 80 μm or less. By setting the third distance C to be 30 μm or more, the plurality of wires 40 and the like can be prevented from being exposed to the outside. Further, by setting the third distance C to 160 μm or less, the first region on the surface of the insulating member 60 located between the inner end portion 61 and the top portion 63 is less likely to excessively protrude toward the plurality of light-emitting elements 20. Accordingly, the possibility that light emitted from each of the plurality of light-emitting elements 20 including the outermost light-emitting element 20a reaches the insulating member 60 can be reduced. That is, stray light is less likely to be emitted from the light-emitting device 1.

Further, in a cross-sectional view illustrated in FIG. 2, a distance, in the height direction of the light-emitting device, between the top portion 63 of the insulating member 60 and a plane of the first upper surface 10a of the first substrate 10 is defined as a second distance B. The second distance B is preferably 280 μm or more and 620 μm or less. The second distance B is more preferably 400 μm or more and 580 μm or less, and even more preferably 450 μm or more and 540 μm or less. Setting the second distance B to be 280 μm or more can prevent the plurality of wires and the like from being exposed to the outside. Further, setting the second distance B to 620 μm or less can reduce the possibility of the top portion 63 having an excessive height. Accordingly, the possibility that light emitted from each of the plurality of light-emitting elements 20 including the outermost light-emitting element 20a reaches the insulating member 60 can be reduced. That is, stray light is less likely to be emitted from the light-emitting device 1.

Further, a distance, in the height direction of the light-emitting device, between the top portion 43 of the wire 40 and the first upper surface 10a of the first substrate 10 is defined as a fourth distance D. In order to further effectively reduce the possibility that stray light is emitted from the light-emitting device 1, the fourth distance D is preferably 100 μm or more and 400 μm or less. The fourth distance D is more preferably 150 μm or more and 270 μm or less, and even more preferably 160 μm or more and 240 μm or less. Unlike the case illustrated in FIG. 2, if no wire 40 appears in a cross-sectional view, a distance, in the height direction of the light-emitting device, between a top portion 43 of a wire 40 located closest to the line II-II of FIG. 1 and the first upper surface 10a of the first substrate 10 may be defined as the fourth distance D. In such a case, the fourth distance D may be measured by any measurement method.

The outer end portion 64 is the outermost portion of the insulating member 60. As illustrated in FIG. 2, the outer end portion 64 reaches the second dam structure 55 in a cross-sectional view. The outer end portion 64 is preferably located at approximately the same position as the top portion of the second dam structure 55 or located inward of the top portion of the second dam structure 55 in a cross-sectional view. With this configuration, the outward movement of the insulating member 60 can be reliably dammed.

### <First Distance A, Second Distance B, Third Distance C, and Fourth Distance D>

In order to further effectively reduce stray light emitted from the light-emitting device 1, the relationship between the first distance A and the second distance B satisfies the following formula (1).

$$0.1 \times B \leq A \leq B \qquad ( 1 )$$

Further, the relationship between the second distance B and the third distance C preferably satisfies the following formula (2).

$$0.1 \times B \leq C \leq 0.3 \times B \qquad ( 2 )$$

Further, the relationship between the second distance B and the fourth distance D preferably satisfies the following formula (3).

$$1.5 \times D \leq B \leq 3. \times D \qquad ( 3 )$$

An example of an influence on stray light according to the first distance A and the third distance C will be described by using Experimental Examples 4 to 8 and Comparative Example 1. However, the present disclosure is not limited to the configurations of Experimental Examples 4 to 8.

The first distance A, the second distance B, and the third distance C are different for each of Experimental Examples 4 to 8 and Comparative Example 1. Experimental Examples 4 to 8 are examples in which the relationship between the first distance A and the second distance B satisfies the above formula (1) (see Table 4 below). Experimental Examples 4 to 8 are also examples in which the relationship between the third distance C and the second distance B satisfies the above formula (2) (see Table 5 below). Conversely, Comparative Example 1 is an example in which the relationship between the first distance A and the second distance B does not satisfy the above formula (1). The fourth distance D in each of Experimental Examples 4 to 8 and Comparative Example 1 was set to be the same (210 μm).

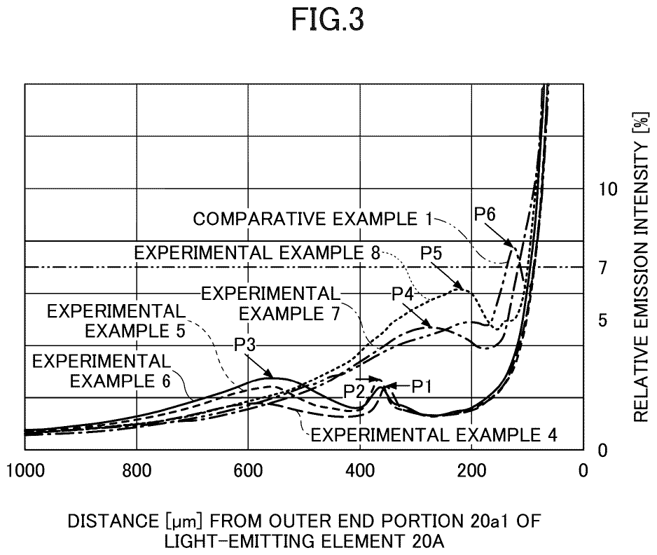

In Experimental Examples 4 to 8 and Comparative Example 1, emission intensity at each position located outward of the outer end portion 20a1 of the outermost light-emitting element 20a was measured. The emission intensity was measured by using 2D spectroradiometer SR5000 manufactured by Topcon Technohouse Corporation. The results of the measured emission intensity in Experimental Examples 4 to 8 and Comparative Example 1 will be described with reference to FIG. 3. FIG. 3 is a graph illustrating an emission intensity distribution measured at positions located outward of the outer end portion 20a1 of the outermost light-emitting element 20a in each of Examples 4 to 8 and Comparative Example 1. The horizontal axis of the graph illustrated in FIG. 3 indicates a distance (μm) from the position in the Y-axis direction of the outer end portion 20a1 of the light-emitting element 20a illustrated in FIG. 2 to a position located away from the outer end portion 20a1 to the −Y side. The larger the numerical value on the horizontal axis, the farther the position is away from the outer end portion 20a1 of the light-emitting element 20a to the −Y side. The vertical axis of the graph illustrated in FIG. 3 represents the relative emission intensity of light at the position outward of the outer end portion 20a1 of the light-emitting element 20a. The relative emission intensity on the vertical axis of the graph of FIG. 3 is a percentage of emission intensity when the maximum value of the peak emission intensity in a region overlapping the plurality of light-emitting elements 20 in a top view is set to 100%.

As illustrated in FIG. 3, in each curve of Experimental Examples 4 to 8 and Comparative Example 1, a projecting portion indicating an increase region in which the emission intensity of light was increased at a position located outward of the outer end portion 20a1 of the light-emitting element 20a was observed (for example, portions indicated by reference numerals P1 to P6 in FIG. 3). The increase region is derived from, for example, light reflected by a member such as the insulating member 60 located outward of the light-emitting element 20a, among lights emitted from the plurality of light-emitting elements 20. The greater the relative emission intensity of light in an increase region is, the more the light emitted at a position located outward of the outer end portion 20a1 of the light-emitting element 20a is likely to be visually recognized from the outside. That is, among lights in increase regions, light in an increase region having a relatively high emission intensity becomes stray light. In the present specification, light in an increase region having a relative emission intensity of 7% or more is described as stray light. However, this is for convenience of description, and even if an increase region having a relative emission intensity of 7% or more does not appear at a position outward of an outer end portion 20a1 of a light-emitting element 20a, such a light-emitting device is not excluded from the scope of the present disclosure.

As illustrated in FIG. 3, a plurality of increase regions were observed in an emission intensity distribution of each example except for Experimental Example 7. In examples in which a plurality of increase regions were observed, an increase region having the highest relative emission intensity was set as a representative region, and it was determined whether stray light was emitted based on whether the relative emission intensity of light in the representative region was 7% or more. As used herein, the term “increase region” means an increase region having the highest relative emission intensity in each example.

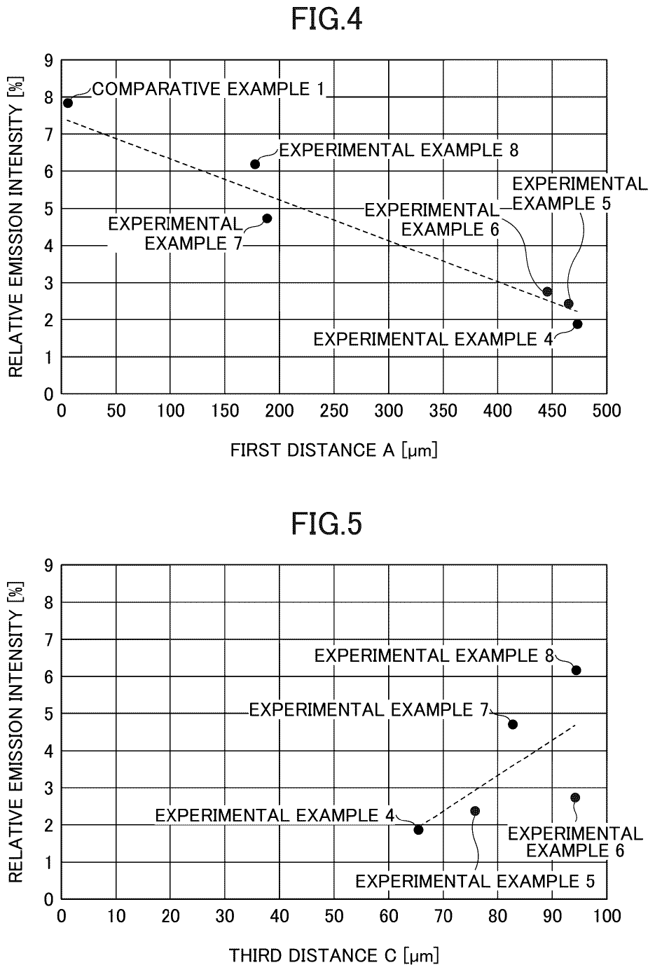

Next, an influence on stray light according to the first distance A and the third distance C will be described with reference to Table 4 and Table 5 and FIG. 4 and FIG. 5. Table 4 indicates “first distance A,” “second distance B,” “first distance A/second distance B,” and “relative emission intensity of light in increase region” in each of Experimental Examples 4 to 8 and Comparative Example 1. Table 5 indicates “third distance C,” “second distance B,” “third distance C/second distance B,” and “relative emission intensity of light in increase region” in each of the Experimental Examples 4 to 8. FIG. 4 is a graph illustrating a relationship between the first distance A and the relative emission intensity of light in each of the increase regions. The horizontal axis of FIG. 4 represents the first distance A. The vertical axis of FIG. 4 represents the relative emission intensity of light in each of the increase regions. FIG. 5 is a graph illustrating a relationship between the third distance C and the relative emission intensity of light in each of the increase regions. The horizontal axis of FIG. 5 represents the third distance C. The vertical axis of FIG. 5 represents the relative emission intensity of light in each of the increase regions.

TABLE 4

| | | | | RELATIVE |
|---|---|---|---|---|
| | | | | EMISSION |
| | | | [FIRST | INTENSITY (%) |
| | FIRST | SECOND | DISTANCE A/ | OF LIGHT IN |
| | DISTANCE A | DISTANCE B | SECOND | INCREASE |
| | (μm) | (μm) | DISTANCE B] | REGION |
| EXPERIMENTAL | 472.9 | 486.3 | 0.97 | 1.9 |
| EXAMPLE 4 | | | | |
| EXPERIMENTAL | 464.7 | 514.7 | 0.90 | 2.4 |
| EXAMPLE 5 | | | | |
| EXPERIMENTAL | 444.9 | 553.6 | 0.80 | 2.7 |
| EXAMPLE 6 | | | | |
| EXPERIMENTAL | 188 | 550.6 | 0.34 | 4.7 |
| EXAMPLE 7 | | | | |
| EXPERIMENTAL | 177.5 | 559 | 0.32 | 6.2 |
| EXAMPLE 8 | | | | |
| COMPARATIVE | 5 | 491 | 0.01 | 7.8 |
| EXAMPLE 1 | | | | |

TABLE 5

| | | | | RELATIVE |
|---|---|---|---|---|
| | | | | EMISSION |
| | | | [THIRD | INTENSITY (%) |
| | THIRD | SECOND | DISTANCE C/ | OF LIGHT IN |
| | DISTANCE C | DISTANCE B | SECOND | INCREASE |
| | (μm) | (μm) | DISTANCE B] | REGION |
| EXPERIMENTAL | 65.5 | 486.3 | 0.13 | 1.9 |
| EXAMPLE 4 | | | | |
| EXPERIMENTAL | 75.9 | 514.7 | 0.15 | 2.4 |
| EXAMPLE 5 | | | | |
| EXPERIMENTAL | 94.3 | 553.6 | 0.17 | 2.7 |
| EXAMPLE 6 | | | | |
| EXPERIMENTAL | 82.8 | 550.6 | 0.15 | 4.7 |
| EXAMPLE 7 | | | | |
| EXPERIMENTAL | 94.4 | 559 | 0.17 | 6.2 |
| EXAMPLE 8 | | | | |

Referring to Experimental Example 6 and Experimental Example 8 in which the second distance B had similar values and the third distance C had similar values, respectively, as illustrated in Table 4, in Experimental Example 6 in which the first distance A had a large value, the relative emission intensity of light in the increase region was decreased. This tendency also appears in the graph illustrated in FIG. 4. According to the graph illustrated in FIG. 4, when the first distance A is 200 μm, the relative emission intensity of light in an increase region can be reduced to about 5%. When the first distance A is 400 μm, the relative emission intensity of light in an increase region can be reduced to about 3%. On the other hand, in Comparative Example 1 in which the first distance A had a smallest value, the relative emission intensity of light in the increase region exceeded 7%. That is, in Comparative Example 1, stray light was emitted at a position located outward of the outer end portion 20a1 of the light-emitting element 20a. From the results, it was confirmed that as the first distance A decreases, the possibility of stray light being emitted increases, and as the first distance A increases, the possibility of stray light being emitted decreases.

Further, as indicated in Table 4, in Experimental Examples 4 to 8, in each of which the relationship between the first distance A and the second distance B satisfies the above formula (1), light having a high relative emission intensity corresponding to stray light was not emitted at positions located outward of the outer end portion 20a1 of the light-emitting element 20a. Conversely, in Comparative Example 1 in which the relationship between the first distance A and the second distance B does not satisfy the above formula (1), stray light was emitted. That is, when the relationship between the first distance A and the second distance B satisfies the above formula (1), the possibility of stray light being emitted was reduced.

Further, referring to Experimental Example 4 and Experimental Example 5 in which the first distance A had similar values and the second distance B had similar values, respectively, as indicated in Table 5, in Experimental Example 4 in which the third distance C had a small value, the relative emission intensity of light in the increase region was decreased. This tendency also appears in the graph illustrated in FIG. 5. On the other hand, in Experimental Example 8 in which the third distance C had the largest value, the relative emission intensity of light in the increase region was the highest as compared to the other Experimental Examples. From these results, it was confirmed that as the third distance C increases, the possibility of stray light being emitted increases, and as the third distance C decreases, the possibility of stray light being emitted decreases.

Further, as indicated in Table 5, in Experimental Examples 4 to 8, in each of which the relationship between the third distance C and the second distance B satisfies the above formula (2), light having a high relative emission intensity corresponding to stray light was not emitted at the positions located outward of the outer end portion 20a1 of the light-emitting element 20a. That is, when the relationship between the third distance C and the second distance B satisfies the above formula (2), the possibility of stray light being emitted was reduced.

### <Method of Manufacturing Light-Emitting Device 1>

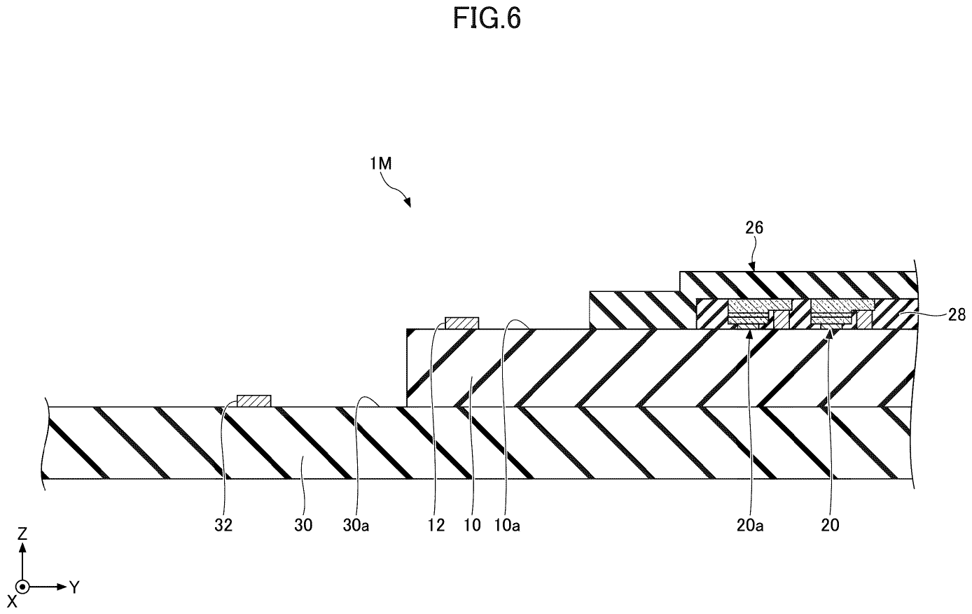

Next, a method of manufacturing the light-emitting device 1 according to the embodiment will be described with reference to FIG. 6 to FIG. 10. FIG. 6 to FIG. 10 are partial cross-sectional views schematically illustrating cross sections taken along the YZ plane, which illustrate the method of manufacturing the light-emitting device 1 according to the embodiment.

The method of manufacturing the light-emitting device 1 according to the embodiment includes, for example, a step of preparing an intermediate body 1M, a step of connecting a wire 40, a step of forming a first dam structure 50, a step of forming a second dam structure 55, and a step of forming an insulating member 60.

First, the step of preparing the intermediate body 1M is performed. As illustrated in FIG. 6, the prepared intermediate body 1M includes a first substrate 10, a plurality of light-emitting elements 20, a phosphor layer 26, and a second substrate 30.

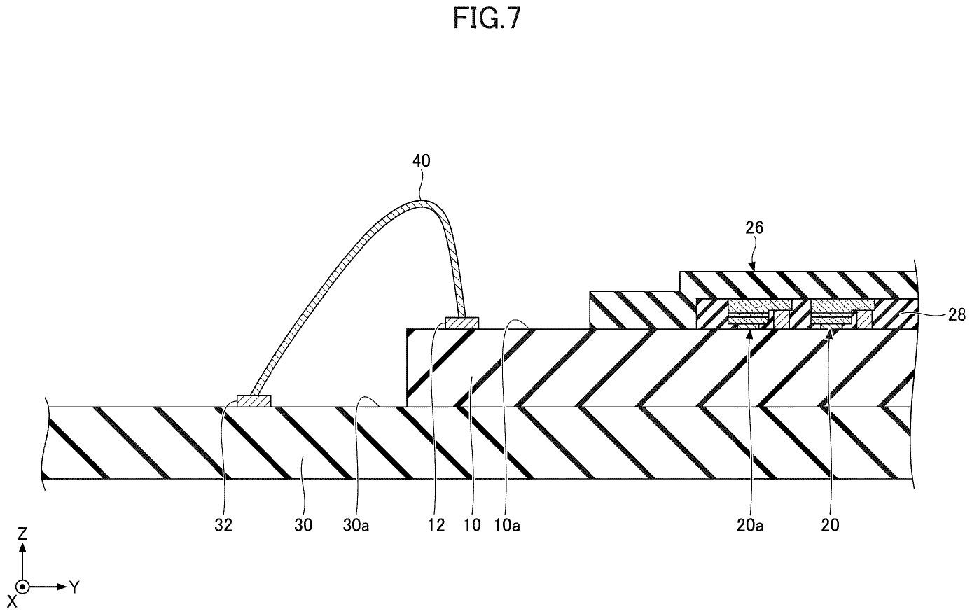

Subsequently, the step of connecting the wire 40 is performed. As illustrated in FIG. 7, one end of the wire 40 is bonded to a first wiring part 12 disposed on a first upper surface 10a of the first substrate 10, and the other end of the wire 40 is bonded to a second wiring part 32 disposed on a second upper surface 30a of the second substrate 30, by using a connection method such as wire bonding. In this manner, the wire 40 electrically connects the first wiring part 12 and the second wiring part 32.

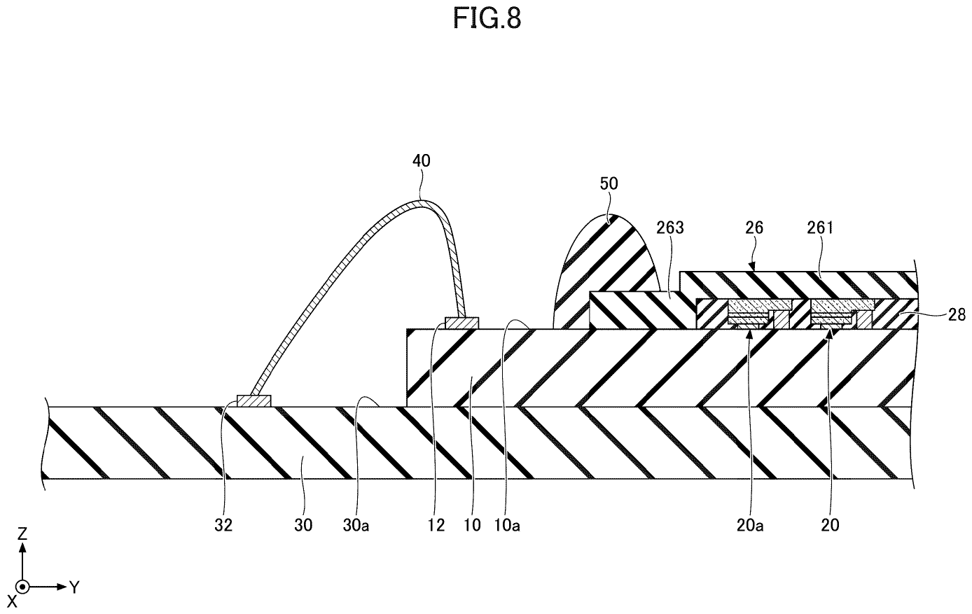

Subsequently, the step of forming the first dam structure 50 is performed. The first dam structure 50 is formed so as to surround the plurality of light-emitting elements 20. At this time, as illustrated in FIG. 8, the first dam structure 50 is preferably formed so as to straddle an extending portion 263 of the phosphor layer 26 and the first upper surface 10a of the first substrate 10. Examples of a method of forming the first dam structure 50 include a method of using a discharge mechanism including a storage that stores a cured material to be the first dam structure 50 and a nozzle that communicates with the storage to apply the material to be the first dam structure 50. For example, the material to be the first dam structure 50 is applied to a region surrounding the plurality of light-emitting elements 20 via the nozzle of the discharge mechanism. Thereafter, the applied material to be the first dam structure 50 is cured by using, for example, any heating method. In this manner, the first dam structure 50 is formed. However, the method of forming the first dam structure 50 is not limited thereto.

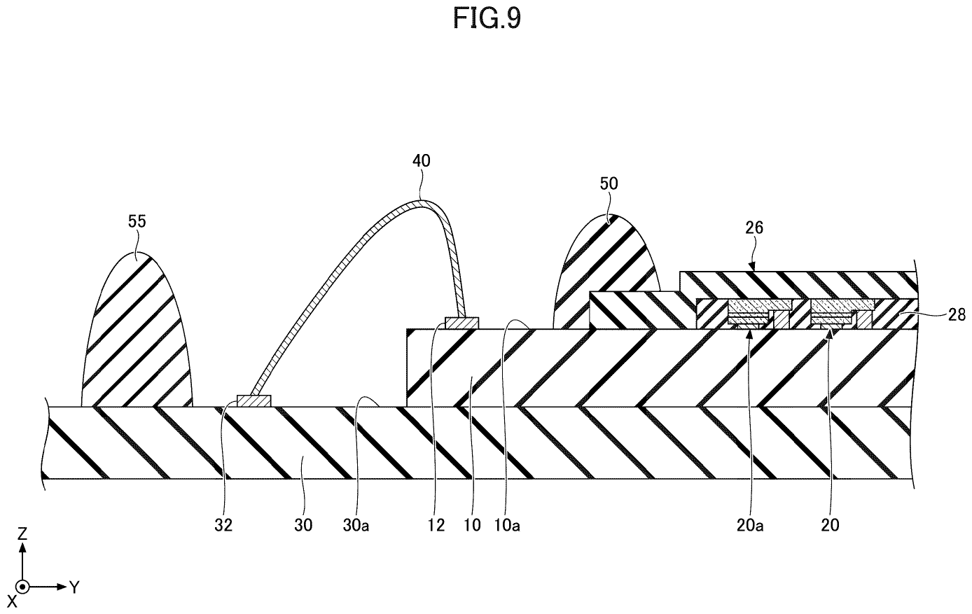

Subsequently, the step of forming the second dam structure 55 is performed. The second dam structure 55 is formed on the second upper surface 30a of the second substrate 30 so as to surround the outer periphery of the first substrate 10. At this time, as illustrated in FIG. 9, the second dam structure 55 is formed outward relative to the wire 40. Similar to the method of forming the first dam structure 50, examples of a method of forming the second dam structure 55 include a method of using a discharge mechanism including a storage that stores an uncured material to be the second dam structure 55 and a nozzle that communicates with the storage to apply the material to be the second dam structure 55. For example, the material to be the second dam structure 55 is applied to a region surrounding the outer periphery of the first substrate 10 and located outward relative to the wire 40 via the nozzle of the discharge mechanism. Thereafter, the applied material to be the second dam structure 55 is cured by using, for example, any heating method. In this manner, the second dam structure 55 is formed. However, the method of forming the second dam structure 55 is not limited thereto.

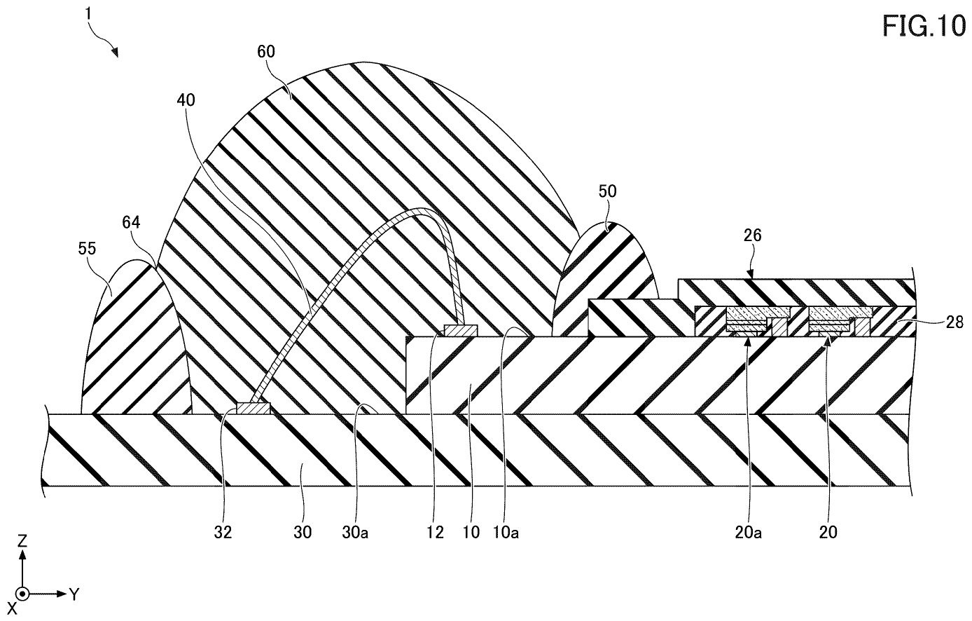

Subsequently, the step of forming the insulating member 60 is performed. The insulating member 60 is formed in a region between the first dam structure 50 and the second dam structure 55. At this time, as illustrated in FIG. 10, the insulating member 60 covers the first wiring part 12, the second wiring part 32, and the wire 40. Similar to the method of forming the first dam structure 50 and the method of forming the second dam structure 55, examples of a method of forming the insulating member 60 include a method of using a discharge mechanism including a storage that stores an uncured material to be the insulating member 60 and a nozzle that communicates with the storage to apply the material to be the insulating member 60. For example, the material to be the insulating member 60 is applied to a region between the first dam structure 50 and the second dam structure 55 via the nozzle of the discharge mechanism. Thereafter, the applied material to be the insulating member 60 is cured by using, for example, any heating method. In this manner, the insulating member 60 is formed. However, the method of forming the insulating member 60 is not limited thereto.

The light-emitting device 1 is manufactured through the above steps. In the example described with reference to FIG. 6 to FIG. 10, the second dam structure 55 is formed after the first dam structure 50 is formed, but the first dam structure 50 may be formed after the second dam structure 55 is formed. Further, the method of manufacturing the light-emitting device 1 may include steps other than the steps described with reference to FIG. 6 to FIG. 10.

### First Modification of Embodiment

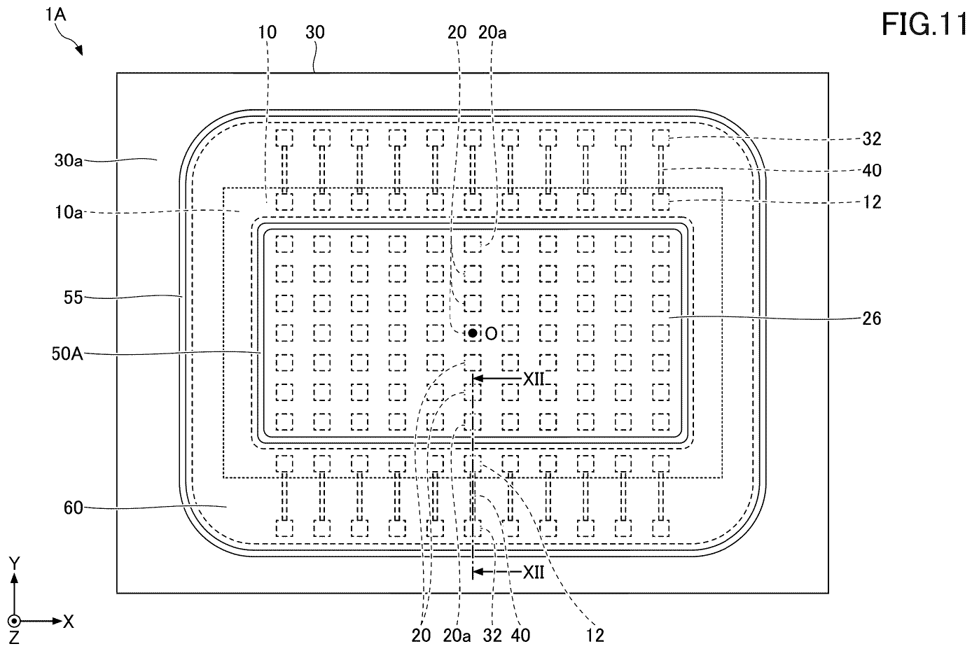

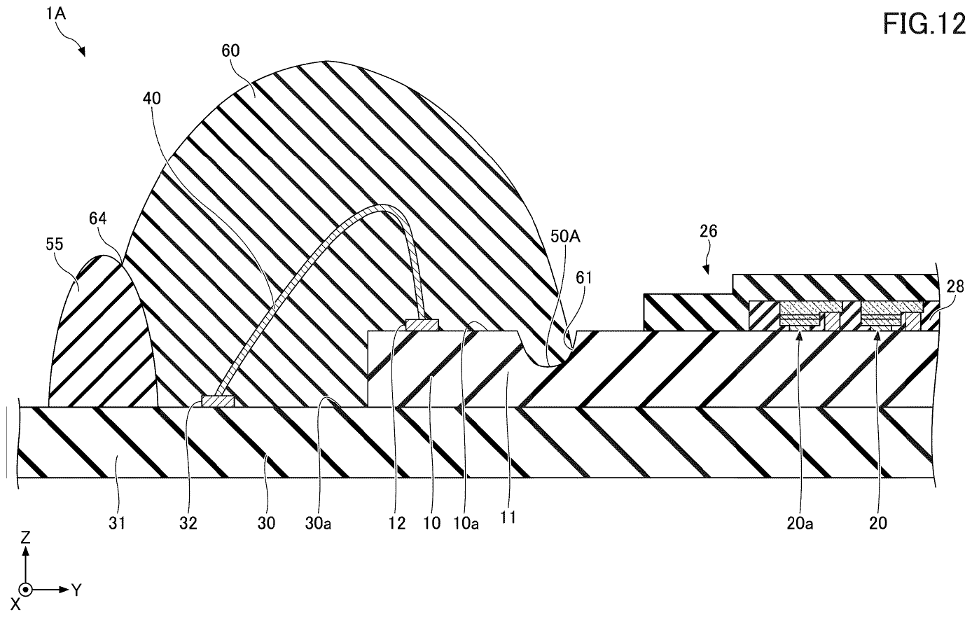

Next, a light-emitting device 1A according to a first modification of the embodiment will be described with reference to FIG. 11 and FIG. 12. FIG. 11 is a top view schematically illustrating the upper surface of the light-emitting device 1A according to the first modification of the embodiment. FIG. 12 is a partial cross-sectional view schematically illustrating a cross section of a part of the light-emitting device 1A according to the first modification of the embodiment, taken along line XII-XII of FIG. 11. In the light-emitting device 1A according to the first modification, the same components as those of the embodiment are denoted by the same reference numerals, and a description thereof will be omitted as appropriate. The cross section of the light-emitting device 1A illustrated in FIG. 12 is an example of a cross section passing through a first substrate, an outermost light-emitting element of a plurality of light-emitting elements, a first dam structure, and an insulating member. That is, in the description with reference to FIG. 12, “in a cross-sectional view” can be rephrased as “in a cross section.”

The configuration of a first dam structure 50A of the light-emitting device 1A according to the first modification differs from the configuration of the first dam structure 50 according to the embodiment. Specifically, as illustrated in FIG. 11 and FIG. 12, the first dam structure 50A is a groove-shaped structure recessed from the first upper surface 10a of the first substrate 10, and is located so as to surround the plurality of light-emitting elements 20 in a top view. In other words, the first dam structure 50A is a frame-shaped recessed part provided in the first upper surface 10a of the first substrate 10. In the light-emitting device 1A, an inner end portion 61 of an insulating member 60 is located on the inner surface of the first dam structure 50A. The inner surface of the first dam structure 50A includes an intersection of the first upper surface 10a and the recessed portion. Even when the first dam structure 50A is a groove-shaped structure recessed from the first upper surface 10a of the first substrate 10, the insulating member 60 can be dammed. Further, because the first dam structure 50A is a groove-shaped structure recessed from the first upper surface 10a of the first substrate 10, the first dam structure 50A can be formed by removing a predetermined region of the first upper surface 10a by a processing method such as etching. Therefore, as compared to the first dam structure 50 according to the embodiment, which uses a resin material or the like and protrudes upward, the processing easiness and the processing accuracy of the first dam structure 50A can be improved.

### Second Modification of Embodiment

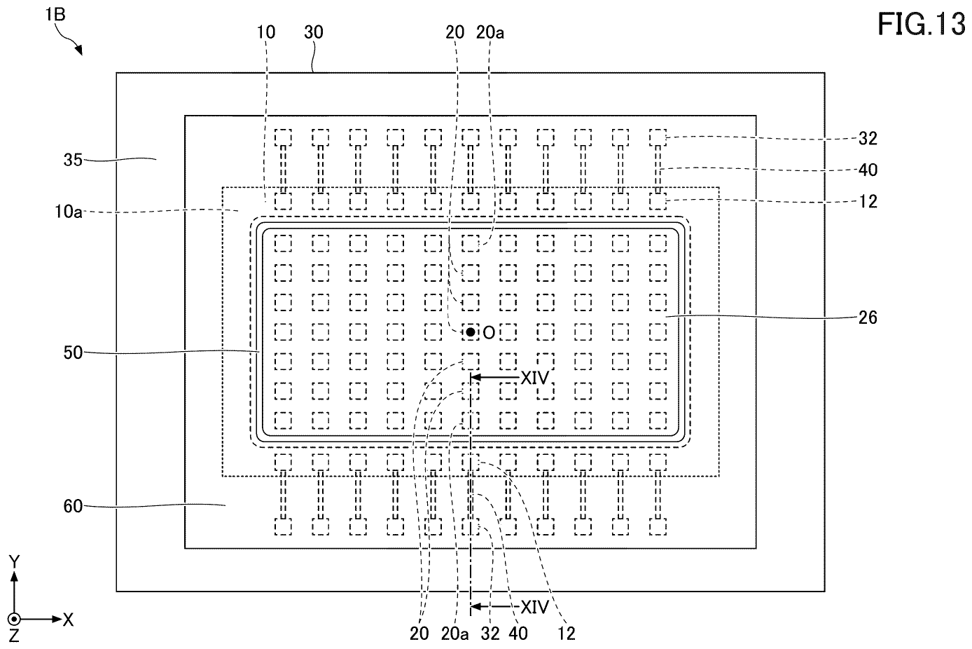

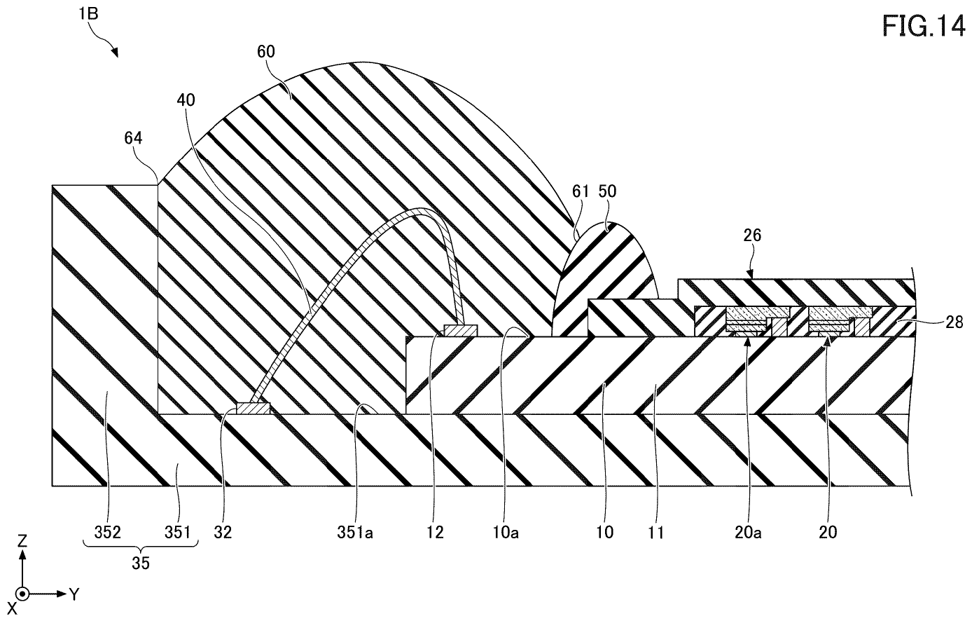

Next, a light-emitting device 1B according to a second modification of the embodiment will be described with reference to FIG. 13 and FIG. 14. FIG. 13 is a top view schematically illustrating the upper surface of the light-emitting device 1B according to the second modification of the embodiment. FIG. 14 is a partial cross-sectional view schematically illustrating a cross section of a part of the light-emitting device 1B according to the second modification of the embodiment, taken along line XIV-XIV of FIG. 13. In the light-emitting device 1B according to the second modification, the same components as those of the embodiment are denoted by the same reference numerals, and a description thereof will be omitted as appropriate. The cross section of the light-emitting device 1B illustrated in FIG. 14 is an example of a cross section passing through a first substrate, an outermost light-emitting element of a plurality of light-emitting elements, a first dam structure, and an insulating member. That is, in the description with reference to FIG. 14, “in a cross-sectional view” can be rephrased as “in a cross section.”

The configuration of a second substrate 35 of the light-emitting device 1B according to the second modification differs from the configuration of the second substrate 30 according to the embodiment. As illustrated in FIG. 13 and FIG. 14, the light-emitting device 1B does not include a second dam structure 55.

As illustrated in FIG. 14, the second substrate 35 includes a bottom portion 351 on which the first substrate 10 is disposed, and a lateral wall portion 352 extending upward from the bottom portion 351. In the second substrate 35, an upper surface 351a of the bottom portion 351 corresponds to the second upper surface on which a first substrate 10 is disposed. A second wiring part 32 is disposed on the upper surface 351a of the bottom portion 351.

The lateral wall portion 352 is disposed outward of an insulating member 60 in a top view. In addition, an outer end portion 64 of the insulating member 60 reaches the lateral wall portion 352. FIG. 14 illustrates only the lateral wall portion 352 extending upward from the outer edge on the −Y side of the bottom portion 351; however, the lateral wall portion 352 may have a region extending upward from each of the outer edge on the +Y side of the bottom portion 351, the outer edge on the +X side of the bottom portion 351, and the outer edge on the −X side of the bottom portion 351. That is, the lateral wall portion 352 may be disposed in a frame shape so as to surround the outer edges of the insulating member 60 in a top view.

As illustrated in FIG. 14, the second substrate 35 includes the lateral wall portion 352 extending upward from the bottom portion 351, and thus the insulating member 60 can be dammed by the lateral wall portion 352. Accordingly, a second dam structure 55 is not required. As a result, the number of processes of manufacturing the light-emitting device 1B can be reduced as compared to the number of processes of manufacturing the light-emitting device 1 according to the embodiment. As a result, costs can be reduced.

Although embodiments have been described in detail above, the above-described embodiments are non-limiting examples, and various modifications and substitutions can be made to the above-described embodiments without departing from the scope described in the claims.

According to one embodiment of the present disclosure, a light-emitting device that reduces stray light can be provided.

What is claimed is:

1. A light-emitting device comprising:
a first substrate having a first upper surface and comprising a first wiring part disposed on the first upper surface;
a plurality of light-emitting elements disposed on the first upper surface of the first substrate, wherein the first wiring part is located outward of the plurality of light-emitting elements;
a second substrate having a second upper surface on which the first substrate is disposed, and comprising a second wiring part disposed on the second upper surface;
a wire electrically connecting the first wiring part and the second wiring part;
a first dam structure disposed on the first upper surface of the first substrate so as to surround the plurality of light-emitting elements; and
a light-shielding insulating member disposed outward of the first dam structure in a top view, covering the wire, the first wiring part, and the second wiring part, and comprising an inner end portion reaching the first dam structure, wherein:
in a cross section passing through at least the first substrate, an outermost light-emitting element of the plurality of light-emitting elements, the first dam structure, and the insulating member, when a distance between a straight line passing through the inner end portion and perpendicular to the first upper surface and a straight line passing through an outer end portion of the outermost light-emitting element and perpendicular to the first upper surface is defined as a first distance A, and a distance, in a height direction of the light-emitting device, between a top portion of the insulating member and a plane of the first upper surface of the first substrate is defined as a second distance B, and
the first distance A and the second distance B satisfy a formula:
$$0.1 \times B \leq A \leq B .$$

2. The light-emitting device according to claim 1, wherein:
the first distance A is 50 μm or more and 490 μm or less, and
the second distance B is 280 μm or more and 620 μm or less.

3. The light-emitting device according to claim 1, wherein:
in the cross section, when, in a direction perpendicular to a straight line connecting the inner end portion to the top portion of the insulating member, a longest distance between the straight line and a region on a surface of the insulating member located between the inner end portion and the top portion is defined as a third distance C, and
the second distance B and the third distance C satisfy a formula:
$$0.1 \times B \leq C \leq 0.3 \times B .$$

4. The light-emitting device according to claim 3, wherein the third distance C is 30 μm or more and 160 μm or less.

5. The light-emitting device according to claim 1, wherein:
when, in the height direction of the light-emitting device, a distance between a top portion of the wire and the plane of the first upper surface of the first substrate is defined as a fourth distance D,
the second distance B and the fourth distance D satisfy a formula:
$$1.5 \times D \leq B \leq 3. \times D .$$

6. The light-emitting device according to claim 1, wherein the first dam structure is a frame-shaped structure protruding upward from the first upper surface of the first substrate.

7. The light-emitting device according to claim 6, wherein:
the first dam structure is light-transmissive,
a height of the inner end portion of the insulating member from the upper surface of the first substrate is greater than heights of upper surfaces of the plurality of light-emitting elements of the light-emitting device from the upper surface of the first substrate, and
the insulating member has a recessed portion extending from the inner end portion to the first upper surface of the first substrate in the cross section.

8. The light-emitting device according to claim 1, further comprising:
a phosphor layer disposed on the plurality of light-emitting elements, wherein
a thickness of the phosphor layer is 28 μm or less.

9. The light-emitting device according to claim 8, wherein the phosphor layer contains a rare earth aluminate phosphor having a composition represented by a formula:
$${Y}_{( 3 - y )} {Al}_{( 5 - x )} {Ga}_{x} {O}_{12} : {Ce}_{y}$$
where x and y are numbers satisfying 0.00<x≤3.00 and 0.015≤y≤0.20, respectively.

10. The light-emitting device according to claim 9, wherein:
the phosphor layer contains a resin portion and a phosphor including the rare earth aluminate phosphor,
content of the phosphor including the rare earth aluminate phosphor is 100 parts by mass or more and 150 parts by mass or less with respect to 100 parts by mass of the resin portion, and
the rare earth aluminate phosphor has an average particle diameter of 1 μm or more and 5 μm or less.

11. The light-emitting device according to claim 8, wherein:
the phosphor layer comprises:
a body portion covering upper surfaces of the plurality of light-emitting elements, and
an extending portion continuous with the body portion and extending outward from the body portion in the top view,
the first dam structure is a frame-shaped structure protruding upward from the first upper surface of the first substrate, and
the first dam structure is disposed so as to straddle the extending portion of the phosphor layer and the first upper surface of the first substrate, in the cross section.

12. The light-emitting device according to claim 11, wherein:
the first dam structure is light-transmissive,
a height of the inner end portion of the insulating member from the upper surface of the first substrate is greater than heights of an upper surface of the body portion and an upper surface of the extending portion of the phosphor layer from the upper surface of the first substrate, and
the insulating member has a recessed portion extending from the inner end portion to the first upper surface of the first substrate in the cross section.

13. The light-emitting device according to claim 6, further comprising:
a second dam structure having a frame shape and disposed on the second upper surface of the second substrate, wherein:
an outer end portion of the insulating member, located outward of the top portion of the insulating member, reaches the second dam structure, and
a height of the second dam structure from the second upper surface is greater than a height of the first dam structure from the first upper surface.

14. The light-emitting device according to claim 1, wherein:
the second substrate comprises:
a bottom portion on which the first substrate is disposed, and
a lateral wall portion extending upward from the bottom portion and disposed outward of the insulating member in the top view, and
an outer end portion of the insulating member, located outward of the top portion of the insulating member, reaches the lateral wall portion.

15. The light-emitting device according to claim 1, wherein:
the first dam structure is a groove-shaped structure recessed from the first upper surface of the first substrate, and
the inner end portion of the insulating member is located on an inner surface of the first dam structure.
